(19) United States
(12) Patent Application Publication
(10) Pub. No.: US 2025/0167738 A1
(43) Pub. Date: May 22, 2025

(54) POWER AMPLIFIER INTEGRATED CIRCUIT WITH TUNABLE IMPEDANCE MATCHING

(71) Applicant: NXP B.V., Eindhoven (NL)

(72) Inventors: Erwin Janssen, Veldhoven (NL); Mohamad El Ozeir, Toulouse (FR); Didier Salle, Toulouse (FR)

(21) Appl. No.: 18/590,512

(22) Filed: Feb. 28, 2024

(30) Foreign Application Priority Data
Nov. 20, 2023 (EP) 23307006.9

(51) Int. Cl. H03F 1/56; G01R 31/28; H03F 3/24; H03H 7/38

(52) U.S. Cl. CPC H03F 1/565; G01R 31/2822; H03F 3/245; H03H 7/38; H03F 2200/105

(57) ABSTRACT

A power amplifier integrated circuit with a tunable impedance matching network and associated methods of testing and operation are provided. The power amplifier integrated circuit includes a power amplifier having an output, an output node coupled to the output of the power amplifier, and a tunable impedance matching network. The tunable impedance matching network includes a tunable inductor coupled to the output node. The tunable inductor includes switches configured to selectively modify an inductance of the tunable inductor. The switches may be configured to modify the tunable inductor to have different inductances in respective testing and functional modes.

### TECHNICAL FIELD

Embodiments of the subject matter described herein relate generally to power amplifiers, including power amplifiers with tunable impedance matching networks.

### BACKGROUND

Integrated circuits, such as power amplifier integrated circuits, are typically fabricated using multi-step processes, typically including photolithographic processes, that form multiple integrated circuit dies (e.g., tens, hundreds, thousands, or more, depending on the respective die and wafer dimensions) on a single semiconductor wafer. Integrated circuit performance may vary from die to die on a given wafer. Due to such performance variation, integrated circuit dies are typically tested at various points during the fabrication process to determine whether each integrated circuit meets predefined power or performance specifications. Integrated circuit die that are determined to have failed to meet such power and/or performance specifications are typically discarded, while those that do meet these specifications are typically retained and used in an end product.

While on-wafer testing of integrated circuit dies can be useful for identifying underperforming dies that should be discarded, it is common for acceptably-performing die to be misidentified as underperforming during such testing. Such misidentification results in undesirably lower yield (typically defined as the percentage of dies of a finished wafer that are determined to perform acceptably), which might be avoided with improved testing accuracy.

### SUMMARY

A brief summary of various exemplary embodiments is presented below. Some simplifications and omissions may be made in the following summary, which is intended to highlight and introduce some aspects of the various exemplary embodiments, without limiting the scope. Detailed descriptions of an exemplary embodiment adequate to allow those of ordinary skill in the art to make and use these concepts will follow in later sections.

In an example embodiment, an integrated circuit includes a power amplifier having an output, an output node coupled to the output of the power amplifier, and a tunable impedance matching network including a tunable inductor coupled to the output node. The tunable inductor includes multiple switches configured to selectively modify the tunable inductor to have a first inductance in a testing mode and a second inductance in a functional mode.

In one or more embodiments, the inductor includes a first terminal coupled to the output node, a second terminal, a first segment coupled to the first terminal, a second segment coupled to the second terminal, and a third segment that is selectively coupled to the first segment and the second segment via the multiple switches.

In one or more embodiments, the multiple switches include a first switch coupled between the first segment and the second segment, a second switch coupled between the first segment and the third segment, and a third switch coupled between the second segment and the third segment.

In one or more embodiments, the first switch is configured to connect the first segment to the second segment in the testing mode, the second switch is configured to be open in the testing mode, and the third switch is configured to be open in the testing mode.

In one or more embodiments, the first switch is configured to be open in the functional mode, the second switch is configured to connect the first segment to the third segment in the functional mode, and the third switch is configured to connect the third segment to the second segment in the functional mode.

In one or more embodiments, the tunable inductor further includes a metal shield interposed between the multiple of switches and the first, second, and third segments.

In one or more embodiments, the first and second segments are arranged to form a first loop, the third segment is arranged to form a second loop, and the first and second loops are concentric.

In one or more embodiments, the integrated circuit further includes a variable voltage source, and the third segment includes a center tap and the variable voltage source is configured to further modify the impedance of the tunable inductor by providing a voltage at the center tap.

In an example embodiment, a method includes setting an output impedance of a power amplifier integrated circuit to a first impedance value in a testing mode by controlling switches of a tunable inductor coupled to an output node of the power amplifier integrated circuit, and setting the output impedance of the power amplifier integrated circuit to a second impedance value in a functional mode by controlling the switches of the tunable inductor. The tunable inductor is coupled to the output node of the power amplifier integrated circuit.

In one or more embodiments, in the testing mode, controlling the switches of the tunable inductor includes causing a first switch of the switches to remain in a closed state, the first switch being coupled between a first segment of the tunable inductor and a second segment of the tunable inductor, causing a second switch of the switches to remain in an open state, the second switch being coupled between the first segment and a third segment of the tunable inductor, and causing a third switch of the switches to remain in an open state, the third switch being coupled between the second segment and the third segment.

In one or more embodiments, in the functional mode, controlling the switches of the tunable inductor includes causing the first switch to remain in an open state, causing the second switch to remain in a closed state, causing the third switch to remain in the closed state.

In one or more embodiments, the first segment and the second segment are arranged to form a first loop, the third segment is arranged to form a second loop, and the first and second loops are concentric.

In one or more embodiments, the method further includes determining, in the test mode, a process corner type of the power amplifier integrated circuit, determining, in the test mode, a tuning voltage having a predetermined association with the process corner type, applying, in the test mode, the determined tuning voltage at the tunable inductor, and calibrating, in the test mode, an output power of the power amplifier while applying the determined tuning voltage at the tunable inductor.

In one or more embodiments, the method further includes configuring, in the test mode, a power amplifier of the power amplifier integrated circuit to produce a maximum output power, determining, in the test mode, a tuning voltage to be applied at the tunable inductor that minimizes reflected power detected by an isolated peak power detector while the power amplifier is producing the maximum output power, and calibrating, in the test mode, an output power of the power amplifier while applying the tuning voltage at the tunable inductor.

In an example embodiment, a system includes a signal source configured to generate a signal; an antenna, and an integrated circuit coupled between the signal source and the antenna. The integrated circuit includes a power amplifier having an output, the power amplifier being configured to amplify the signal and provide the amplified signal to the antenna, an output node coupled between the output of the power amplifier and the antenna, and a tunable impedance matching network that includes a tunable inductor coupled to the output node, the tunable inductor including switches configured to modify the tunable inductor to have a selected one of a first inductance associated with a testing mode and a second inductance associated with a functional mode.

In one or more embodiments, the tunable inductor includes a first terminal coupled to the output node, a second terminal, a first segment coupled to the first terminal, a second segment coupled to the second terminal, and a third segment that is selectively coupled to the first segment and the second segment via the switches.

In one or more embodiments, the switches include a first switch coupled between the first segment and the second segment, a second switch coupled between the first segment and the third segment, and a third switch coupled between the second segment and the third segment.

In one or more embodiments, in the functional mode, the first switch is configured to be in an open state, the second switch is configured to connect the first segment to the third segment, and the third switch is configured to connect the third segment to the second segment.

In one or more embodiments, the first and second segments are arranged to form a first loop, the third segment arranged to form a second loop, and the first and second loops are concentric.

In one or more embodiments, the system further includes a variable voltage source, and the third segment includes a center tap and the variable voltage source is configured to further modify the impedance of the tunable inductor by providing a voltage at the center tap.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures. Elements in the figures are illustrated for simplicity and clarity and have not necessarily been drawn to scale. The figures along with the detailed description are incorporated and form part of the specification and serve to further illustrate examples, embodiments and the like, and explain various principles and advantages, in accordance with the present disclosure, wherein:

FIG. 1 is a block diagram illustrating an example test system for the on-wafer testing and characterization of a power amplifier integrated circuit having a tunable impedance matching network, in accordance with one or more embodiments;

FIG. 2 is a block diagram illustrating an example system that includes a packaged power amplifier integrated circuit having a tunable impedance matching network, in accordance with one or more embodiments.

FIG. 3 is a diagram illustrating a tunable inductor that may be included in a power amplifier integrated circuit, such as the power amplifier integrated circuits of FIGS. 1 and 2, in accordance with one or more embodiments;

FIG. 4 is a diagram illustrating a tunable inductor that may be included in a power amplifier integrated circuit, such as the power amplifier integrated circuits of FIGS. 1 and 2, where a variable voltage source is coupled to a center tap of one of the segments of the tunable inductor, in accordance with one or more embodiments;

FIG. 5 is a diagram illustrating top and bottom perspective views of an example tunable inductor that may be included in a power amplifier integrated circuit, such as the power amplifier integrated circuits of FIGS. 1 and 2, in accordance with one or more embodiments;

FIG. 6. is a process flow chart describing a method of calibrating a power amplifier, which includes determining and applying a tuning voltage at a tunable inductor coupled to the power amplifier, such as the tunable inductor of FIG. 4, based on a backend process corner association of the power amplifier, in accordance with one or more embodiments;

FIG. 7. is a process flow chart describing a method of calibrating a power amplifier, which includes determining and applying a tuning voltage at a tunable inductor coupled to the power amplifier, such as the tunable inductor of FIG. 4, where the tuning voltage is determined as the tuning voltage that minimizes reflected power while the power amplifier outputs maximum power, in accordance with one or more embodiments;

FIG. 8. is a chart illustrating output power distributions, during on-wafer testing, of power amplifier integrated circuits representing three different types of backend process corners with and without a tunable impedance matching network disposed at the output of the power amplifier, in accordance with one or more embodiments; and

FIG. 9. is a chart illustrating output power distributions, during on-wafer testing, of power amplifier integrated circuits representing three different types of backend process corners with a tunable impedance matching network disposed at the output of the power amplifier, where a tuning voltage is applied at the tunable matching network to compensate for backend process variations, in accordance with one or more embodiments.

### DETAILED DESCRIPTION

The following detailed description is merely illustrative in nature and is not intended to limit the embodiments of the subject matter or the application and uses of such embodiments. Furthermore, there is no intention to be bound by any expressed or implied theory presented in the preceding technical field, background, or the following detailed description.

For simplicity and clarity of illustration, the drawing figures illustrate the general manner of construction, and descriptions and details of well-known features and techniques may be omitted for sake of brevity. Additionally, elements in the drawing figures are not necessarily drawn to scale. For example, the dimensions of some of the elements or regions in the figures may be exaggerated relative to other elements or regions to help improve understanding of embodiments described herein.

The terms “first,” “second,” “third,” “fourth” and the like in the description and the claims, if any, may be used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Furthermore, the terms “comprise,” “include,” “have” and any variations thereof, are intended to cover non-exclusive inclusions, such that a process, method, article, or apparatus that comprises a list of elements is not necessarily limited to those elements but may include other elements not expressly listed or inherent to such process, method, article, or apparatus. The term “coupled,” as used herein, is defined as directly or indirectly connected in an electrical or non-electrical manner. As used herein the terms “substantial” and “substantially” mean sufficient to accomplish the stated purpose in a practical manner and that minor imperfections, if any, are not significant for the stated purpose. As used herein, the words “exemplary” and “example” mean “serving as an example, instance, or illustration.” Any implementation described herein as exemplary or an example is not necessarily to be construed as preferred or advantageous over other implementations.

Directional references such as “top,” “bottom,” “left,” “right,” “above,” “below,” and so forth, unless otherwise stated, are not intended to require any preferred orientation and are made with reference to the orientation of the corresponding figure or figures for purposes of illustration.

For the sake of brevity, conventional semiconductor fabrication techniques may not be described in detail herein. In addition, certain terms may also be used herein for reference only, and thus are not intended to be limiting. For instance, the terms “first”, “second”, and other such numerical terms referring to structures do not imply a sequence or order unless clearly indicated by the context.

Various embodiments described herein relate to power amplifier integrated circuits with tunable impedance matching networks and associated methods of testing and operation. Conventionally, power amplifier integrated circuits (ICs) undergo on-wafer testing while not properly terminated. That is, output nodes of such conventional power amplifier ICs are left open, whereas such output nodes would be coupled to a load, such as an antenna, in practice. As a result, the impedance at the power amplifier output during testing resembles that of a parallel capacitor. Because of this improper termination, conclusions regarding the viability of a given power amplifier IC conventional testing and characterization methods tend to be inaccurate and can result in viable power amplifier ICs being discarded, undesirably lowering yield.

Embodiments described herein address the above problem by providing a tunable impedance matching network at the output of the power amplifier (e.g., a tunable inductor coupled between the output of the power amplifier and a ground or reference terminal) of a power amplifier IC to adjust the impedance at the output of the power amplifier to emulate that of a properly terminated load (e.g., the expected load impedance when the power amplifier IC is packaged and coupled to an antenna). The tunable impedance matching network may be configured to have a first impedance during a testing mode and a second impedance during a functional mode.

The first impedance of the tunable impedance matching network causes the impedance at the output of the power amplifier to be similar to the expected load impedance when the power amplifier IC is packaged and coupled to an antenna. The second impedance of the tunable impedance matching network provides an impedance match between the power amplifier and the expected load (e.g., around 50Ω) after packaging and connection (e.g., to an antenna). In this way, the tunable impedance matching network may provide better impedance matching during on-wafer testing of the power amplifier IC (e.g., in the testing mode), which may improve the accuracy of output power testing of the power amplifier, while still achieving an acceptable impedance match during normal operation of the power amplifier after packaging and connection to an antenna or other load (e.g., in the functional mode).

It should be noted that the tunable impedance matching network causes additional power losses (e.g., losses of around 0.35 dB to around 0.45 dB) during normal operation of the power amplifier IC. Such losses may be considered a tradeoff for the improved yield from improved output power testing accuracy attributable to the tunable impedance matching network.

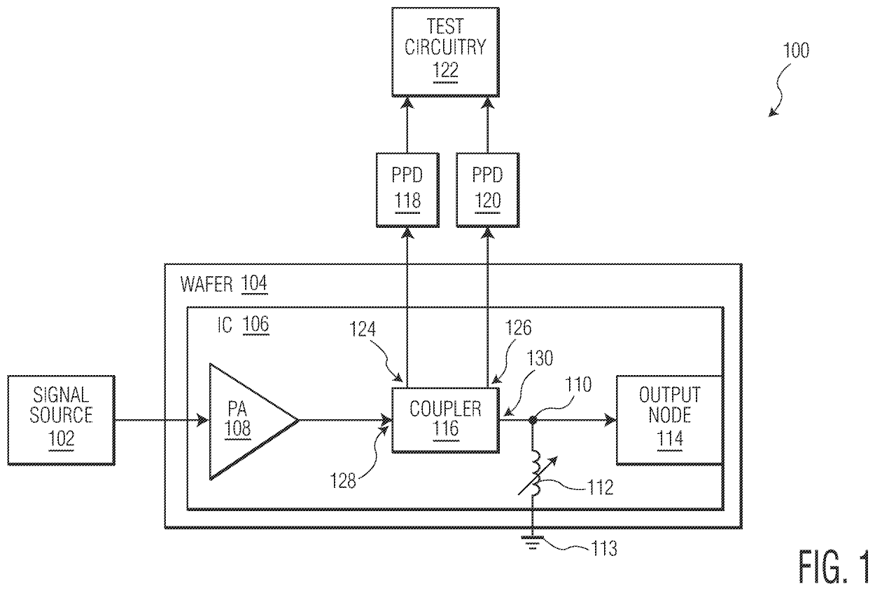

FIG. 1 shows a block diagram of a test system 100 that is configured for on-wafer testing of output power of a power amplifier (PA) 108 of an integrated circuit (IC) 106 (sometimes referred to as a “power amplifier integrated circuit 106”). The test system 100 includes a signal source 102, a directional coupler 116, a first peak power detector (PPD) 118 coupled to an isolated output port 124 of the directional coupler 116, a second PPD 120 coupled to a coupled output port 126 of the directional coupler 116, and test circuitry 122 configured to receive outputs of the first and second PPDs 118 and 120. The IC 106 may be formed on a wafer 104, which may include other power amplifier ICs in addition to the IC 106. The wafer 104 may be a semiconductor wafer that includes silicon (Si), Silicon Carbide (SiC), Gallium Nitride (GaN), Gallium Arsenide (GaAs), or other suitable semiconductor materials, as non-limiting examples. The IC 106 may include at least the power amplifier 108 and a tunable inductor 112. The tunable inductor 112 may be part of a tunable impedance matching network at the output of the power amplifier 108. It should be understood that additional well-known circuitry (e.g., additional impedance matching circuitry, supply circuitry, or other applicable circuitry) may be included at inputs and/or outputs of the power amplifier 108, which is not shown or described in detail here to avoid unnecessarily obscuring the various example embodiments.

The power amplifier 108 includes an input that is coupled to the signal source 102 and an output that is coupled to the output node 114 via the directional coupler 116, which may be configured as a reflectometer. The power amplifier 108 may be configured as a class A, class B, class AB, class D, or class E amplifier, as non-limiting examples. In one or more embodiments, the signal source 102 may be a radio frequency (RF) signal source configured to generate RF signals. In one or more embodiments, the signal source 102 may be included in or controlled by the test circuitry 122.

The directional coupler 116 may include an input port coupled to the output of the power amplifier 108, a through port coupled to the output node 114 and the tunable inductor 112 via a node 110, a coupled output port 126 that is coupled to an input of the second PPD 120, and an isolated output port 124 that is coupled to an input of the first PPD 118.

The output node 114 may be coupled to the output of the power amplifier 108 via the node 110 and the directional coupler 116. In one or more embodiments, the output node 114 may be a conductive pillar, such as a copper pillar. Prior to packaging of the IC 106, the output node 114 may be an open pillar such that, without the inclusion of the tunable inductor 112, the impedance observed at the output of the power amplifier 108 would be similar to that of a parallel capacitor.

The tunable inductor 112 may be coupled between the node 110 and a reference node 113. That is, the tunable inductor 112 may have a first terminal that is coupled to the output of the power amplifier 108 and the output node 114 via the node 110 and may have a second terminal that is coupled to the reference node 113.

In one or more embodiments, the power amplifier 108 is single-ended (i.e., having a single output), and the tunable inductor 112 is coupled between the node 110 and the reference node 113. In one or more such embodiments, the reference node 113 is, configured to provide a ground voltage, a common voltage, or another suitable reference potential.

In one or more other embodiments, the power amplifier 108 has two differential outputs, the node 110 is coupled along the output path of a first differential output of the amplifier 108, and the tunable inductor 112 is coupled between the node 110 and an additional node that is disposed along the output path of a second differential output (not shown) of the amplifier 108, with the reference node 113 representing a virtual ground disposed at a center point along the length of the tunable inductor 112.

As will be described, the tunable inductor 112 is configurable in multiple modes. In the present example, the tunable inductor 112 is configured in a testing mode. In the testing mode, the tunable inductor 112 is configured to have an inductance (around 75 pH to around 150 pH in accordance with one or more embodiments, as a non-limiting example) that provides a suitable impedance match at the output of the power amplifier during on-wafer testing.

The first PPD 118 includes an input that is coupled to the isolated output port 124 of the directional coupler 116 and an output that is coupled to a first input of the test circuitry 122.

The second PPD 120 includes an input that is coupled to the coupled output port 126 of the directional coupler 116 and an output that is coupled to a second input of the test circuitry 122. Each of the first and second PPDs 118 and 120 may be configured to measure or otherwise detect peak power of signals received at their respective inputs, to generate voltage signals representing the detected or measured peak power, and to provide such voltage signals at their respective outputs.

The test circuitry 122 may be coupled to the first and second PPDs 118 and 120 via its first and second inputs, respectively. In one or more embodiments, the test circuitry 122 may include automatic test equipment (ATE). The test circuitry 122 may include a computer processor, computer memory, one or more computer-readable electronic storage devices, a power source, and/or power detection circuitry, as non-limiting examples. The test circuitry 122 may be configured to receive the voltage signals (representing peak power measurements) from the outputs of the PPDs 118 and 120.

When performing on-wafer testing of the IC 106, the signal source 102 may be configured to generate a signal (e.g., an oscillating signal, such as a radio frequency (RF) signal) and to provide that signal to an input of the power amplifier 108. The power amplifier 108 may be configured to amplify the signal received from the signal source, generating an amplified signal that is then provided at the output of the power amplifier 108. The power amplifier 108 may provide the amplified signal to the output node 114 via the directional coupler 116. For example, the amplified signal produced by the power amplifier 108 may be received at an input port 128 of the directional coupler 116 and may be provided to the output node 114 via a through port 130 of the directional coupler 116.

Incident power of the amplified signal, representing incident output power of the power amplifier 108, may be sampled by the second PPD 120 via the coupled output port 126. The second PPD 120 may provide a first voltage signal to the test circuitry 122, the first voltage signal representing the measured incident power (e.g., peak incident power) of the amplified signal. Reflected power of the amplified signal received at the through port 130 of the directional coupler 116 may be sampled by the first PPD 118. The first PPD 118 may provide a second voltage signal to the test circuitry 122, the second voltage signal representing the measured reflected power (e.g., peak reflected power) of the amplified signal.

The test circuitry 122 may be configured to determine whether the IC 106 passes output power testing based on at least the peak power measurements generated by the second PPD 120 (i.e., which measures peak power at the coupled output port 126). For example, if a peak power measurement generated by the second PPD 120 is greater than or equal to a predetermined threshold (e.g., around 12.9 dBm as a non-limiting example), the IC 106 may be considered to “pass” and the test circuitry 122 may indicate that the IC 106 is a “good” device (e.g., indicating that the IC 106 is a good device in a computer-readable memory of the test circuitry 122 or indicating that the IC 106 is a good device by leaving it unmarked, as non-limiting examples). Continuing the example, in response to determining a peak power measurement generated by the second PPD 120 is less than the predetermined threshold, the test circuitry 122 may determine that the IC 106 fails output power testing and may indicate that the IC 106 is a “bad” device (e.g., indicating that the IC 106 is a bad device in a computer-readable memory of the test circuitry 122 or indicating that the IC 106 is a bad device by physically marking the IC 106 in some way, such as by application of an ink dot, as non-limiting examples) that should be discarded.

In one or more embodiments, the test circuitry may additionally or alternatively be configured to calibrate the IC 106 by adjusting the power output by the power amplifier and/or tuning the tunable inductor 112. Examples of such calibration processes are described in more detail below.

During on-wafer testing (e.g., in a testing mode), the tunable inductor 112 may be configured to have an inductance that provides a suitable impedance match between the power amplifier 108 and the output node 114. In one or more embodiments, the tunable inductor 112 may include multiple switches (e.g., complementary metal-oxide semiconductor (CMOS) switches, as a non-limiting example), where the configuration of these switches determines the inductance of the tunable inductor 112. Each mode of the tunable inductor (e.g., testing mode or functional mode) may be associated with a particular switch configuration, as described in more detail, below. In one or more embodiments, a tuning voltage may be applied at one or more segments of the tunable inductor 112 to compensate for backend process variations, as described in more detail below. In one or more embodiments, the IC 106 may include logic circuitry configured to control the switches of the tunable inductor 112.

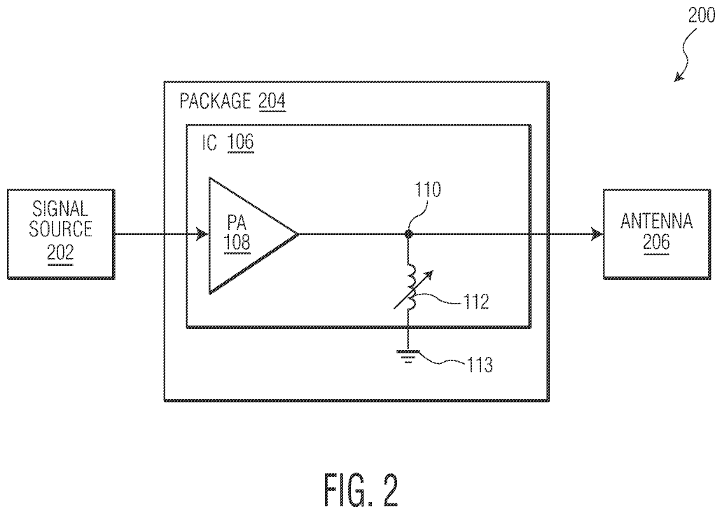

Upon successful on-wafer testing (and, in one or more embodiments, calibration) of the IC 106, the IC 106 may be separated from the wafer 104 (e.g., via dicing) and packaged for use in a device or system. For example, FIG. 2 shows a block diagram of a system 200 that includes a package 204 that includes the IC 106 of FIG. 1, which is configured to generate an amplified signal for transmission using an antenna 206. One or more components of the system 200 may be similar to corresponding components of the system 100 of FIG. 1, with like reference numerals denoting like elements, and description of such components is not necessarily repeated here for sake of brevity.

The system 200 includes a signal source 202, a package 204, and an antenna 206. The package 204 includes the IC 106, which includes the power amplifier 108 and the tunable inductor 112, where the tunable inductor 112 is coupled to the output of the power amplifier 108 and to the antenna via the node 110. During operation of the system 200, the signal source 202 may be configured to generate a signal, such as an RF signal. The power amplifier 108 may receive and amplify the signal generated by the signal source 202 for transmission via the antenna 206.

When implemented in the system 200 the tunable inductor 112 is configured in a functional mode. For example, in the functional mode, the tunable inductor 112 is configured to have an inductance (around 120 pH to around 240 pH in accordance with one or more embodiments, as a non-limiting example) that provides a suitable impedance match at the output of the power amplifier during operation of the system 200. Each mode of the tunable inductor (e.g., testing mode or functional mode) may be associated with a particular switch configuration, as described in more detail, below. In one or more embodiments, a tuning voltage may be applied at one or more segments of the tunable inductor 112 to compensate for backend process variations, as described in more detail below.

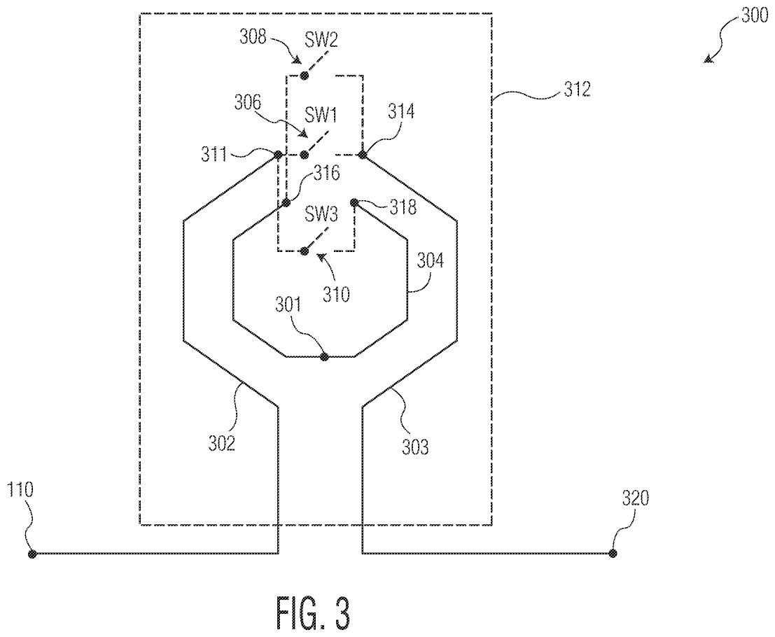

FIG. 3 shows circuitry 300 that includes a tunable inductor 312 (e.g., an example embodiment of the tunable inductor 112 of FIGS. 1 and 2) that includes switches 306, 308, and 310 (also denoted here as SW1, SW2, and SW3, respectively). The switches 306, 308, and 310 may be selectively controlled to modify the inductance of the tunable inductor 312 (e.g., in association with one or more modes, such as the testing mode and the functional mode described above). One or more components of the circuitry 300 may be similar to corresponding components of the system 100 of FIG. 1, with like reference numerals denoting like elements, and description of such components is not necessarily repeated here for sake of brevity.

As shown, the tunable inductor 312 includes a first segment 302, a second segment 303, and a third segment 304. Each of the segments 302, 303, and 304 may be formed form one or more layers of electrically conductive material (e.g., copper, gold, aluminum or any suitable combination or alloy thereof, as non-limiting examples) and may be disposed on a dielectric layer of an IC (e.g., the IC 106 of FIGS. 1 and 2).

The first and second segments 302 and 303 may arranged to form a first substantially octagonal loop. The third segment 304 may arranged to form a second substantially octagonal loop. Here, a “substantially octagonal” loop refers to a loop that is at least partially octagonal in shape and that is not necessarily a closed loop. The first and second substantially octagonal loops formed by the segments 302, 303, and 304 may be concentric, as shown. While the loops formed by the first and second segments 302 and 303 and of the third segment 304, respectively, are shown to be substantially octagonal in the present example, it should be understood that this is illustrative and not limiting, such that other suitable arrangements (e.g., substantially hexagonal or circular loops, as non-limiting examples) of the segments 302, 303 and 304 may be used in one or more other embodiments. In one or more embodiments, a center tap 301 may be disposed at a center point along the length of the third segment 304.

The tunable inductor 312 is coupled between a node 110 and a node 320. In one or more embodiments the node 110 is coupled to a first output path of a first differential output of a power amplifier (e.g., an embodiment of the power amplifier 108 of FIGS. 1 and 2), and the node 320 is coupled to a second output path of a second differential output of the power amplifier. In one or more such embodiments, a center point of the tunable inductor (e.g., located at the center tap 301 when switches 308 and 310 are closed and switch 306 is open or located at the switch 306 when the switches 308 and 310 are open and the switch 306 is closed) acts as a virtual ground or common node for the tunable inductor 312. In one or more other embodiments, the node 110 is coupled to an output path of a single-ended power amplifier (e.g., an embodiment of the power amplifier 108 of FIGS. 1 and 2), and the node 320 is coupled to a reference potential, such as a ground or common reference potential.

The first segment 302 includes a first end that is coupled to the node 110 (i.e., a node that is coupled to the output of a power amplifier) and a second end that is coupled to a node 311. The second segment 303 includes a first end that is coupled to the node 320 and a second end that is coupled to a node 314. The third segment 304 is coupled includes a first end coupled to a node 316 and a second end coupled to a node 318. The first switch 306 is coupled between the node 311 and the node 314, such that the first switch 306 can selectively electrically connect the first segment 302 to the second segment 303. The second switch 308 is coupled between the node 314 and a node 316, such that the second switch 308 can selectively electrically connect the second segment 303 to the third segment 304. The third switch 310 is coupled between the node 311 and the node 318, such that the third switch 310 can selectively electrically connect the first segment 302 to the third segment 304. In one or more embodiments, the switches 306, 308, and 310 may include CMOS switches, as a non-limiting example.

In a first mode (i.e., a testing mode), switches 306, 308, and 310 of the tunable inductor 312 may be configured such that the first switch 306 is closed and the second and third switches 308 and 310 are open, such that the first segment 302 is connected to the second segment 303 through the first switch 306, and the third segment 304 is disconnected from the first and second segments 302 and 303. In the first mode, the tunable inductor 312 may have an inductance of between around 75 pH and around 150 pH, as a non-limiting example.

In a second mode (i.e., a functional mode), switches 306, 308, and 310 of the tunable inductor 312 may be configured such that the first switch 306 is open and the second and third switches 308 and 310 are closed, such that the first segment 302 is connected to the second segment 303 through the second switch 308, the third segment 304, and the third switch 310. In the second mode, the tunable inductor 312 may have an inductance of between around 120 pH and around 240 pH, as a non-limiting example.

That is, the tunable inductor 312 is configured to have a first inductance in the first mode or testing mode and a second inductance in the second mode or functional mode, where the first inductance is different from the second inductance. When configured to have the first inductance in the testing mode, the tunable inductor 312 may provide a suitable impedance match between a power amplifier (e.g., the power amplifier 108 of FIG. 1) and an output node (e.g., the output node 114 of FIG. 1, which may be an open pillar) during on-wafer testing. When configured to have the second inductance in the functional mode, the tunable inductor may a suitable impedance match between the power amplifier and a load (e.g., the antenna 206 of FIG. 2) after packaging of the IC that includes the tunable inductor 312.

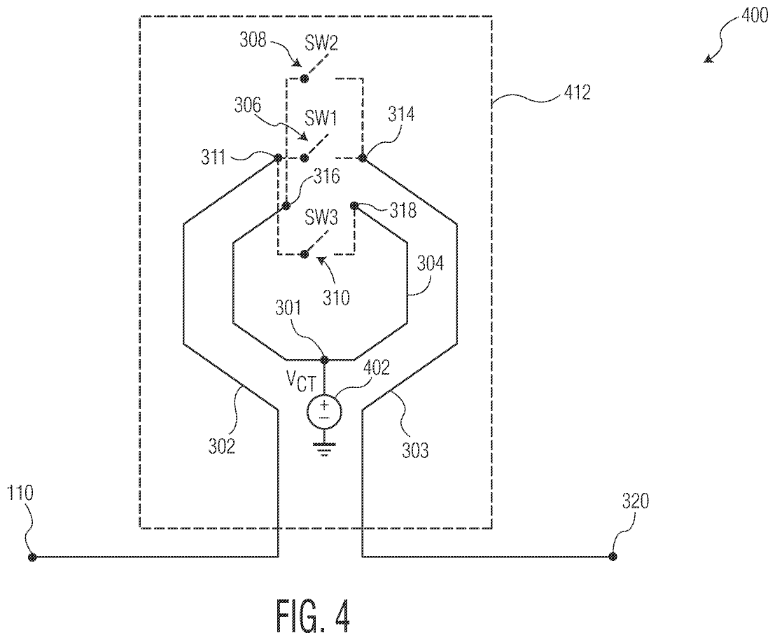

FIG. 4 shows circuitry 400 that includes a tunable inductor 412 (e.g., an example embodiment of the tunable inductor 112 of FIGS. 1 and 2) that includes switches 306, 308, and 310 (also denoted here as SW1, SW2, and SW3, respectively). The switches 306, 308, and 310 may be selectively controlled to modify the inductance of the tunable inductor 412 (e.g., in association with one or more modes, such as the testing mode and the functional mode described above). The tunable inductor 412 is coupled to a variable voltage source via a center tap at one of the segments of the tunable inductor 412 for additional tuning of the inductance of the tunable inductor 412. One or more components of the circuitry 400 may be similar to corresponding components of the system 100 of FIG. 1 and the circuitry 300 of FIG. 3, with like reference numerals denoting like elements, and description of such components is not necessarily repeated here for sake of brevity.

As shown, the tunable inductor 412 includes the segments 302, 303, and 304 and the switches 306, 308, and 310. In the present example, the third segment 304 includes a center tap 301 disposed at a center point along its length, where the center tap 301 is coupled to a variable voltage source 402, which is configured to supply a tuning voltage V_{CT}. In one or more embodiments, the variable voltage source 402 may be included in the IC that includes the tunable inductor 412 (e.g., the IC 106 of FIG. 1). In one or more other embodiments, the variable voltage source 402 may be an external voltage source that is coupled to the IC that includes the tunable inductor 412. The center tap 301 may be coupled to respective source terminals of the switches 308 and 310. During on-wafer testing, when the tunable inductor 412 is in the testing mode, the switches 308 and 310 are closed, and changing the tuning voltage V_{CT} modifies the gate-to-source voltage (V_{gs}) the switches 308 and 310. By modifying the V_{gs} of the switches 308 and 310, the impedance of the switches 308 and 310 is changed, which in turn modifies the impedance of the tunable inductor 412.

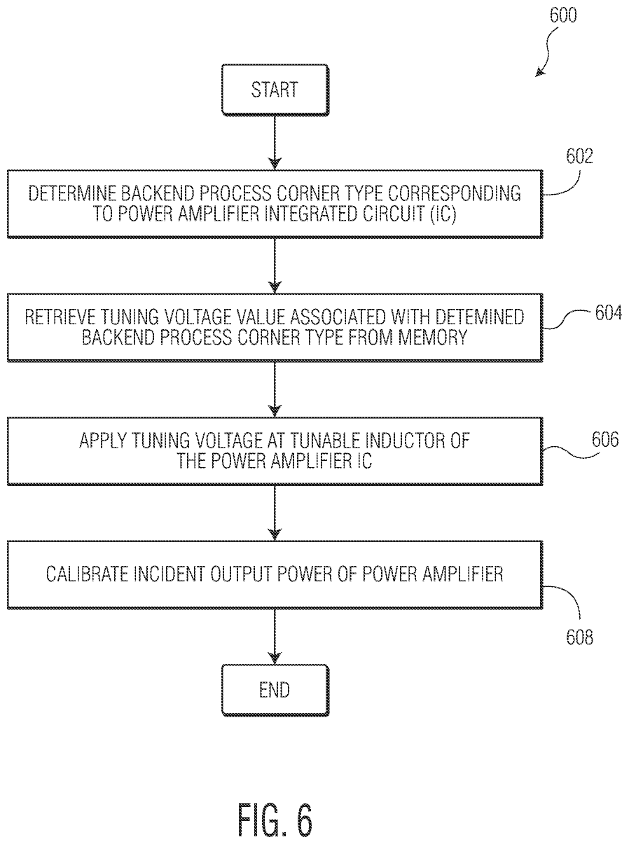

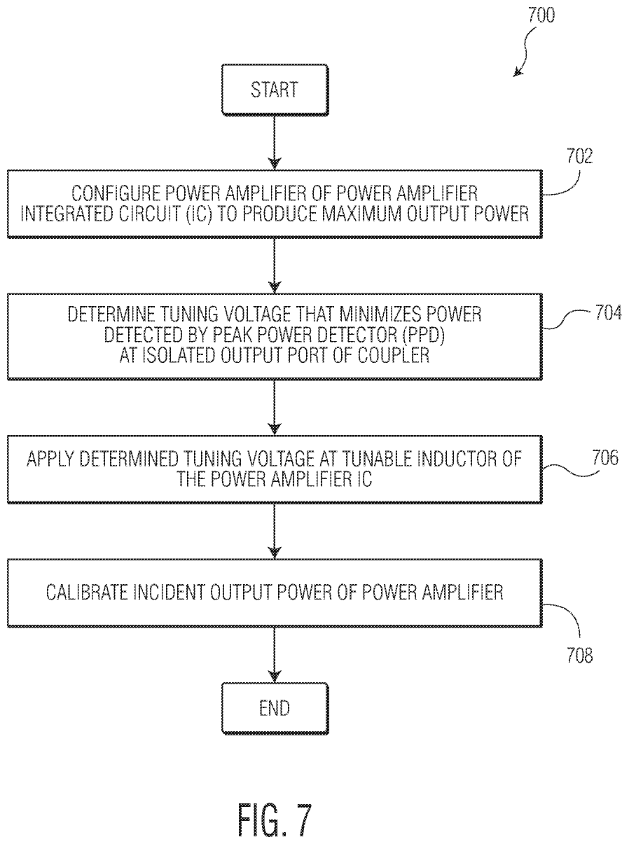

In one or more embodiments, in addition to setting the impedance of the tunable inductor 412 by selectively configuring the switches 306, 308, and 310 in the testing mode, the impedance of the tunable inductor 412 may be further modified by adjusting the tuning voltage V_{CT} to compensate for backend process variations. By applying the tuning voltage V_{CT} to compensate for backend process variations in this way, the accuracy of power output testing of the IC that includes the tunable inductor 412 may be further improved, which may further improve yield. Examples of techniques by which a suitable tuning voltage V_{CT} for backend process variation compensation may be determined and applied during calibration of a power amplifier IC are described in more detail below (e.g., in connection with the methods 600 and 700 of FIGS. 6 and 7, respectively).

It should be understood that the application of a tuning voltage V_{CT} at a center tap 301 of the third segment 304 in the present example is intended to be illustrative and non-limiting. For example, in one or more other embodiments, the control voltages supplied at the gates of the switches 308 and 310 may instead be adjusted to modify the V_{gs} of the switches 308 and 310 in order to modify the impedance of the tunable inductor 412 to compensate for backend process variations.

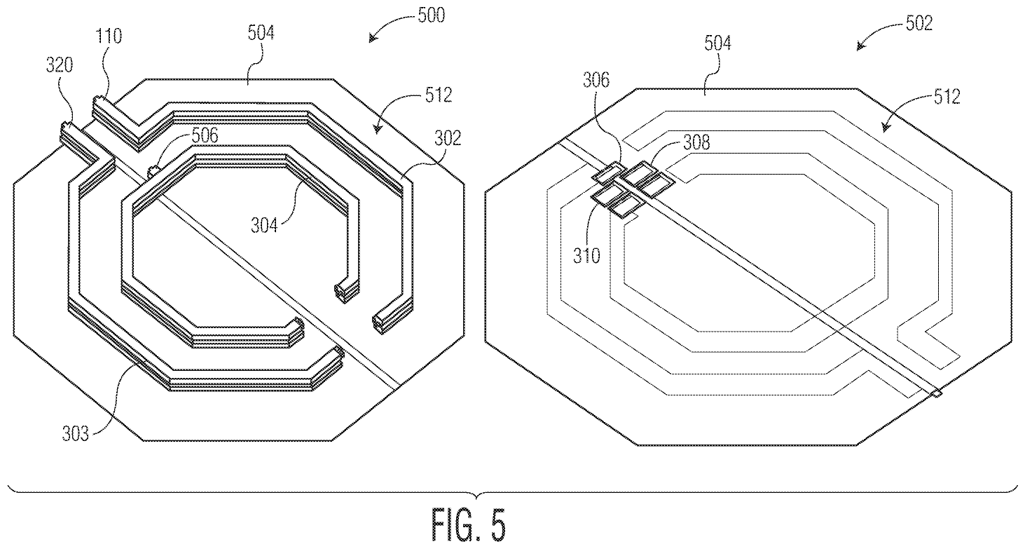

FIG. 5 shows a top perspective view 500 and a bottom perspective view 502 of an example embodiment of a tunable inductor 512 (e.g., an example embodiment of any of the tunable inductor 112 of FIGS. 1 and 2, the tunable inductor 312 of FIG. 3, or the tunable inductor 412 of FIG. 4). One or more components of the tunable inductor 512 may be similar to corresponding components of the circuitry 300 of FIG. 3, with like reference numerals denoting like elements, and description of such components is not necessarily repeated here for sake of brevity.

As shown, the tunable inductor 512 includes the segments 302, 303, and 304 and the switches 306, 308, and 310. In the present example, the segment 304 includes a center tap 506 at a center point along its length. The center tap 506 may be coupled to a variable voltage source configured to supply a tuning voltage (e.g., the variable voltage source 402 of FIG. 4 configured to supply the tuning voltage V_{CT}). The segments 302, 303, and 304 are disposed at a first side of a metal shield layer 504 and may be separated from the metal shield layer 504 by one or more layers of dielectric material. The switches 306, 308, and 310 are disposed at a second side of the metal shield layer 504, opposite the first side. The metal shield layer 504 may advantageously mitigate interference between the switches 306, 308, and 310 and the tunable inductor 512.

FIG. 6 shows an illustrative process flow for a method 600 by which a testing system may determine a tuning voltage for a tunable inductor of a power amplifier IC and calibrate incident output power of a power amplifier of the power amplifier IC. The method 600 may be performed using the testing system 100 of FIG. 1 and the tunable inductor 412 of FIG. 4, in accordance with one or more embodiments. The method 600 is described with reference to elements of the testing system 100 of FIG. 1 and the tunable inductor 412 of FIG. 4. However, it should be understood that this is illustrative and not limiting, at least in that other suitable testing systems may be used to carry out the method 600 in one or more other embodiments.

At block 602, the test circuitry 122 determines a backend process corner type corresponding to the IC 106. For example, the test circuitry 122 may use a ring oscillator to determine which of the TYPICAL, RC_BEST, and RC_WORST backend process corner types corresponds to the IC 106. For example, the frequency of a given signal generated by a ring oscillator of the IC 106 may differ between backend process corner types, such that the backend process corner type of the IC 106 may be determined by measuring the frequency such a signal.

At block 604, the test circuitry 122 retrieves a tuning voltage value associated with the backend process corner type determined at block 602 from a computer-readable memory or storage device that is included in or coupled to the test circuitry 122. In one or more embodiments, a respectively different tuning voltage value may be determined for each backend process corner type and may be stored in the computer-readable memory or storage device. The stored tuning voltage associated with a given backend process corner type may correspond to the tuning voltage that, when supplied to the tunable inductor of the IC 106 (e.g., at the center tap 301 of the tunable inductor 412), suitably compensates for the backend process variations of that backend process corner type, thereby providing a suitable impedance match (e.g., an optimal impedance match) between the power amplifier 108 and the output node 114 in the testing mode. In one or more embodiments, each tuning voltage value may be determined via characterization and testing of ICs belonging to the different backend process corner types or via computer-aided simulation prior to performance of the method 600.

At block 606, the test circuitry 122 causes a tuning voltage having a magnitude equal to the tuning voltage value retrieved at block 604 to be applied to the tunable inductor of the IC 106 (e.g., at the center tap 301 of the tunable inductor 412 by the variable voltage source 402). In one or more embodiments, the value of the tuning voltage may be set based on a value stored in a memory device (e.g., that is coupled to controller configured to control the variable voltage source that supplies the tuning voltage).

At block 608, the test circuitry 122 calibrates incident output power of the power amplifier 108 to be equal to a target output power based on measurements taken by the PPDs 118 and 120, while continuing to apply the tuning voltage to the tunable inductor of the IC 106.

FIG. 7 shows an illustrative process flow for a method 700 by which a testing system may determine a tuning voltage for a tunable inductor of a power amplifier IC and calibrate incident output power of a power amplifier of the power amplifier IC. The method 700 may be performed using the testing system 100 of FIG. 1 and the tunable inductor 412 of FIG. 4, in accordance with one or more embodiments. The method 700 is described with reference to elements of the testing system 100 of FIG. 1 and the tunable inductor 412 of FIG. 4. However, it should be understood that this is illustrative and not limiting, at least in that other suitable testing systems may be used to carry out the method 700 in one or more other embodiments.

At block 702, the test circuitry 122 configures the power amplifier 108 to generate its maximum output power (e.g., the highest magnitude of output power achievable by the power amplifier 108).

At block 704, the test circuitry 122 determines a tuning voltage that, when applied at the tunable inductor of the IC 106 (e.g., at the center tap 301 of the segment 304 of the tunable inductor 412) by a variable voltage source (e.g., the variable voltage source 402) that results in the lowest (i.e., minimum) power measurement at the PPD 118, which is coupled to the isolated output port 124 of the directional coupler 116. That is, the determined tuning voltage minimizes the reflected power received via the through port 130 of the directional coupler 116. In one or more embodiments, the test circuitry may cause the variable voltage source to sweep the voltage value of the tuning voltage, then analyze corresponding peak power measurements of the PPD 118 to determine the tuning voltage that minimizes the reflected power.

At block 706, the test circuitry 122 causes the tuning voltage determined at block 704 to be applied at the tunable inductor of the IC 106 (e.g., at the center tap 301 of the tunable inductor 412 by the variable voltage source 402).

At block 708, the test circuitry 122 calibrates incident output power of the power amplifier 108 to be equal to a target output power based on measurements taken by the PPDs 118 and 120, while the determined tuning voltage is applied to the tunable inductor of the IC 106.

It should be noted that, compared to the method 600 of FIG. 6, the method 700 does not require backend process corner type characterization.

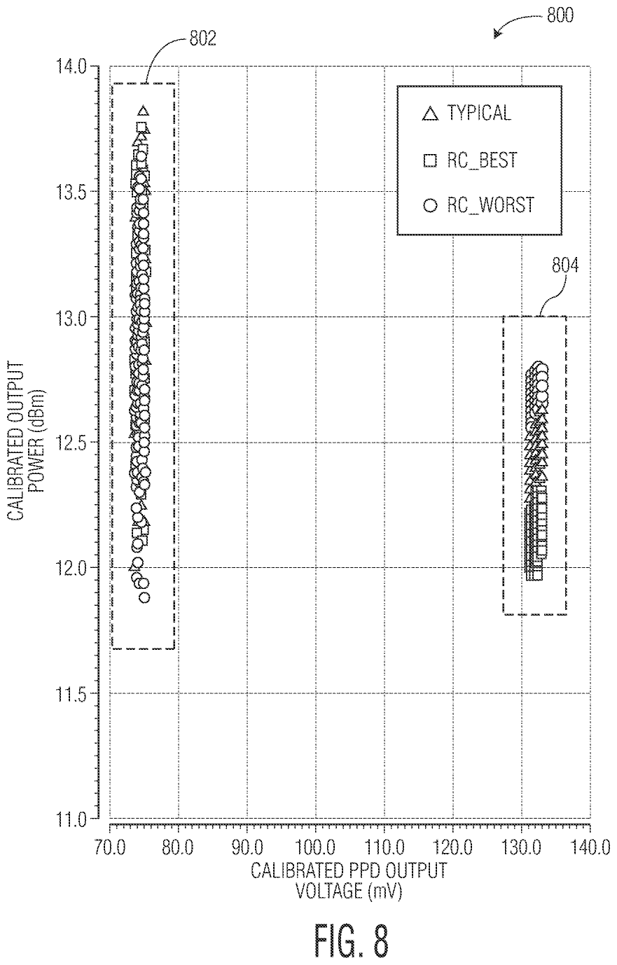

FIG. 8 shows an illustrative chart 800 representing a distribution of PPD output voltage versus output power for a first group 802 of power amplifier ICs and a second group 804 of power amplifier ICs. The power amplifier ICs of each group are categorized according to backend process corner type. Each power amplifier IC of the first group 802 does not include a tunable inductor at its output. Each power amplifier IC of the second group 804 includes a tunable inductor, such as an embodiment of the any of the tunable inductors 112, 312, 412, or 512 of FIGS. 1-5, respectively, at its output (e.g., similar to the arrangement of the IC 106 in the testing system 100 of FIG. 1).

Each IC represented in the groups 802 and 804 belongs to one of three backend process corner types: TYPICAL, RC_BEST, and RC_WORST. Each of these backend process corner type may be defined relative to the resistance and capacitance of interconnects of a given IC, where differences in resistance and capacitance of ICs may be attributed to process variations that result in varying interconnect trace dimensions. For example, an IC of the “TYPICAL” backend process corner type is characterized as having nominal values for interconnect resistance and capacitance. An IC of the “RC_BEST” backend process corner type is characterized as having a minimized (e.g., minimum allowable) interconnect resistance-capacitance (RC) product, corresponding to a smaller than typical interconnect resistance and larger than typical interconnect capacitance. An IC of the “RC_WORST” backend process corner type is characterized as having a maximized (e.g., maximum allowable) interconnect RC product, corresponding to larger than typical interconnect resistance and smaller than typical interconnect capacitance. RC_WORST corners typically correspond to ICs with relatively higher power loss, while RC_BEST corners typically correspond to ICs with relatively lower power loss.

For sake of comparison, the ICs of the first group 802 are calibrated to achieve a PPD output voltage (e.g., the voltage output by the PPD 120 of FIG. 1) of around 75 mV for a target output power of around 12.5 dBm, and the ICs of the second group 804 are calibrated to achieve a PPD output voltage (e.g., the voltage output by the PPD 120 of FIG. 1) of around 130 mV for the same target output power of around 12.5 dBm (where the voltages differ due to differences in coupling factor between the first group 802 and the second group 804).

As shown in the present example, ICs of the first group 802, which lack a tunable inductor, are distributed over a relatively larger range of output power values (from around 11.8 dBm to around 13.8 dBm; corresponding to an accuracy of around +/−1.0 dBm), substantially independent of backend process corner type, during on-wafer testing. In contrast, ICs of the of the second group 804, which each include a tunable inductor at their output (configured in the testing mode, as described above), are distributed over a relatively smaller range of output power values (from around 12.0 dBm to around 12.8 dBm; corresponding to an accuracy of around +/−0.4 dBm), with a distribution that is substantially dependent on backend process corner type. Thus, by including the tunable inductor (e.g., configured in the testing mode in accordance with embodiments described herein), at the outputs of the ICs of the second group 804, the output power testing accuracy is improved by around 1.2 dBm. This corresponds to a 170% improvement in output power testing accuracy for the second group 804 over the first group 802. This improvement in accuracy may advantageously reduce the number of otherwise “good” ICs that are erroneously identified as “bad” ICs (and, therefore, discarded) during on-wafer output power testing, thereby advantageously improving yield.

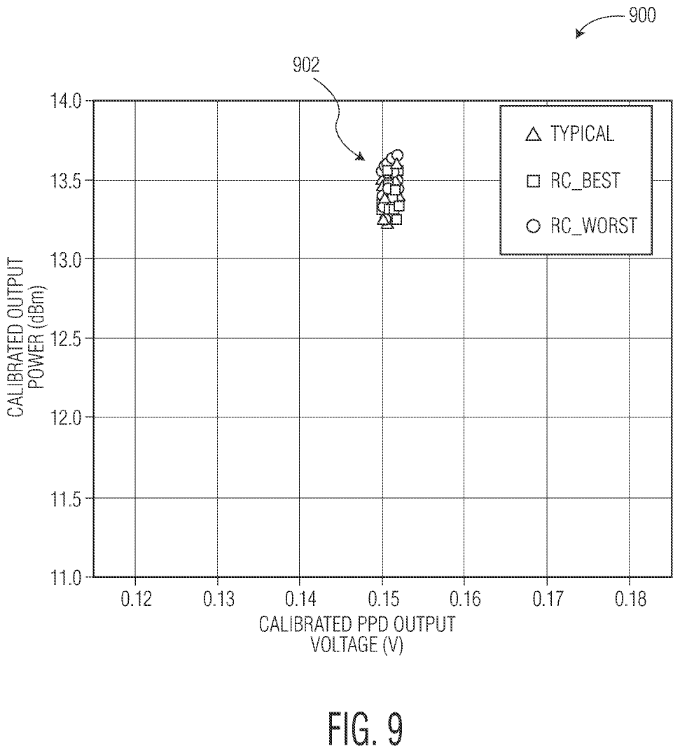

FIG. 9 shows an illustrative chart 900 representing a distribution of PPD output voltage versus output power for a group 902 of power amplifier ICs each having a tunable inductor, such as an embodiment of any of the tunable inductors 112 or 412 of FIGS. 1, 2, and 4, respectively, at its output, where a tuning voltage is applied to the tunable inductor of each IC to compensate for backend process variations (e.g., in accordance with the method 600 of FIG. 6, as a non-limiting example). The power amplifier ICs of the group 902 are categorized according to backend process corner type.

Each IC represented in the group 902 belongs of one of the three backend process corner types described above (i.e., TYPICAL, RC_BEST, and RC_WORST), which are not described again here for sake of brevity. In the present example, each IC of the group 902 is calibrated to achieve a PPD output voltage (e.g., the voltage output by the PPD 120 of FIG. 1) of around 150 mV for a target output power of around 12.5 dBm.

As shown in the present example, ICs of the group 902, each including a power amplifier and a tunable inductor at the output of the power amplifier that is tuned to compensate for backend process variations, are distributed over a relatively smaller range of output power values (from around 13.2 dBm to around 13.6 dBm; corresponding to an accuracy of around +/−0.2 dBm) compared to the groups 802 and 804 of FIG. 8. This corresponds to a 100% improvement in output power testing accuracy for the group 902 over the second group 804 of FIG. 8, and a 340% improvement (reduced to a 50% improvement when accounting for an expected 0.4 dBm insertion loss that may be attributed to the tunable inductor) in output testing accuracy for the group 902 over the first group 802 of FIG. 8. This improvement in accuracy may advantageously reduce the number of otherwise “good” ICs that are erroneously identified as “bad” ICs (and, therefore, discarded) during on-wafer output power testing, thereby advantageously improving yield. Additionally, the distribution of ICs within the group 902 less dependent on backend process corner type, compared to the group 804 of FIG. 8, due to the compensation for backend process variation attributable to applying calibrated tuning voltages to the tunable inductors of the ICs.

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with) another element, and not necessarily mechanically. Thus, although the schematic shown in the figures depict one exemplary arrangement of elements, additional intervening elements, devices, features, or components may be present in one or more embodiments of the depicted subject matter.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

It should also be noted that at least some of the operations for the methods described herein may be implemented using software instructions stored on a computer useable storage medium for execution by a computer. As an example, an embodiment of a computer program product includes a computer useable storage medium to store a computer readable program. The computer-useable or computer-readable storage medium can be an electronic, magnetic, optical, electromagnetic, infrared, or semiconductor system (or apparatus or device). Examples of non-transitory computer-useable and computer-readable storage media include a semiconductor or solid-state memory, magnetic tape, a removable computer diskette, a random-access memory (RAM), a read-only memory (ROM), a rigid magnetic disk, and an optical disk. Current examples of optical disks include a compact disk with read only memory (CD-ROM), a compact disk with read/write (CD-R/W), and a digital video disk (DVD).

Alternatively, embodiments described herein may be implemented entirely in hardware or in an implementation containing both hardware and software elements. In embodiments which use software, the software may include but is not limited to firmware, resident software, microcode, etc.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

1-15. (canceled)

16. An integrated circuit comprising:
a power amplifier having an output;
an output node coupled to the output of the power amplifier; and
a tunable impedance matching network comprising:
a tunable inductor coupled to the output node, the tunable inductor comprising a plurality of switches configured to selectively modify the tunable inductor to have a first inductance in a testing mode and a second inductance in a functional mode.

17. The integrated circuit of claim 16, wherein the tunable inductor comprises:
a first terminal coupled to the output node;
a second terminal;
a first segment coupled to the first terminal;
a second segment coupled to the second terminal; and
a third segment that is selectively coupled to the first segment and the second segment via the plurality of switches.

18. The integrated circuit of claim 17, wherein plurality of switches comprises:
a first switch coupled between the first segment and the second segment;
a second switch coupled between the first segment and the third segment; and
a third switch coupled between the second segment and the third segment.

19. The integrated circuit of claim 18, wherein:
the first switch is configured to connect the first segment to the second segment in the testing mode;
the second switch is configured to be open in the testing mode; and
the third switch is configured to be open in the testing mode.

20. The integrated circuit of claim 19, wherein:
the first switch is configured to be open in the functional mode;
the second switch is configured to connect the first segment to the third segment in the functional mode; and
the third switch is configured to connect the third segment to the second segment in the functional mode.

21. The integrated circuit of claim 18, wherein the tunable inductor further comprises:
a metal shield interposed between the plurality of switches and the first, second, and third segments.

22. The integrated circuit of claim 18, wherein the first and second segments are arranged to form a first loop, the third segment is arranged to form a second loop, and the first and second loops are concentric.

23. The integrated circuit of claim 17, further comprising:
a variable voltage source, wherein the third segment comprises a center tap and the variable voltage source is configured to further modify the impedance of the tunable inductor by providing a voltage at the center tap.

24. A method comprising:
setting an output impedance of a power amplifier integrated circuit to a first impedance value in a testing mode by controlling switches of a tunable inductor coupled to an output node of the power amplifier integrated circuit; and
setting the output impedance of the power amplifier integrated circuit to a second impedance value in a functional mode by controlling the switches of the tunable inductor, wherein the tunable inductor is coupled to the output node of the power amplifier integrated circuit.

25. The method of claim 24, wherein, in the testing mode, controlling the switches of the tunable inductor comprises:
causing a first switch of the switches to remain in a closed state, wherein the first switch is coupled between a first segment of the tunable inductor and a second segment of the tunable inductor;
causing a second switch of the switches to remain in an open state, wherein the second switch is coupled between the first segment and a third segment of the tunable inductor; and
causing a third switch of the switches to remain in an open state, wherein the third switch is coupled between the second segment and the third segment.

26. The method of claim 25, wherein, in the functional mode, controlling the switches of the tunable inductor comprises:
causing the first switch to remain in an open state;
causing the second switch to remain in a closed state; and
causing the third switch to remain in the closed state.

27. The method of claim 25, wherein the first segment and the second segment are arranged to form a first loop, the third segment is arranged to form a second loop, and the first and second loops are concentric.

28. The method of claim 26, further comprising:
determining, in the test mode, a process corner type of the power amplifier integrated circuit;
determining, in the test mode, a tuning voltage having a predetermined association with the process corner type;
applying, in the test mode, the determined tuning voltage at the tunable inductor; and
calibrating, in the test mode, an output power of the power amplifier while applying the determined tuning voltage at the tunable inductor.

29. The method of claim 26, further comprising:
configuring, in the test mode, a power amplifier of the power amplifier integrated circuit to produce a maximum output power;
determining, in the test mode, a tuning voltage to be applied at the tunable inductor that minimizes reflected power detected by an isolated peak power detector while the power amplifier is producing the maximum output power; and
calibrating, in the test mode, an output power of the power amplifier while applying the tuning voltage at the tunable inductor.

30. A system comprising:
a signal source configured to generate a signal;
an antenna;
an integrated circuit coupled between the signal source and the antenna, the integrated circuit comprising:
a power amplifier having an output, wherein the power amplifier is configured to amplify the signal and provide the amplified signal to the antenna;
an output node coupled between the output of the power amplifier and the antenna; and
a tunable impedance matching network comprising:
a tunable inductor coupled to the output node, the tunable inductor comprising a plurality of switches configured to modify the tunable inductor to have a selected one of:
a first inductance associated with a testing mode; or
a second inductance associated with a functional mode.

31. The system of claim 30, wherein the tunable inductor comprises:
a first terminal coupled to the output node;
a second terminal;
a first segment coupled to the first terminal;
a second segment coupled to the second terminal; and
a third segment that is selectively coupled to the first segment and the second segment via the plurality of switches.

32. The system of claim 31, wherein plurality of switches comprises:
a first switch coupled between the first segment and the second segment;
a second switch coupled between the first segment and the third segment; and
a third switch coupled between the second segment and the third segment.

33. The system of claim 32, wherein, in the functional mode:
the first switch is configured to be in an open state;
the second switch is configured to connect the first segment to the third segment; and
the third switch is configured to connect the third segment to the second segment.

34. The system of claim 32, wherein the first and second segments are arranged to form a first loop, the third segment arranged to form a second loop, and the first and second loops are concentric.

35. The system of claim 31, further comprising:
a variable voltage source, wherein the third segment comprises a center tap and the variable voltage source is configured to further modify the impedance of the tunable inductor by providing a voltage at the center tap.
